(19) United States
(12) Patent Application Publication
(10) Pub. No.: US 2013/0176087 A1
(43) Pub. Date: Jul. 11, 2013

(54) ELASTIC WAVE FILTER

(71) Applicant: MURATA MANUFACTURING CO., LTD., Nagaokakyo-shi (JP)

(72) Inventors: Masahiro HOSONUMA, Nagaokakyo-shi (JP); Hiroki WATANABE, Nagaokakyo-shi (JP)

(73) Assignee: MURATA MANUFACTURING CO., LTD., Nagaokakyo-shi (JP)

(21) Appl. No.: 13/781,939

(22) Filed: Mar. 1, 2013

Related U.S. Application Data
(63) Continuation of application No. PCT/JP2011/065839, filed on Jul. 12, 2011.

(30) Foreign Application Priority Data
Oct. 5, 2010 (JP) 2010-225528

(51) Int. Cl. H03H 9/64

(52) U.S. Cl. CPC H03H 9/64
USPC 333/193; 333/195

(57) ABSTRACT

An elastic wave filter that prevents damage caused by ESD is constructed such that a distance between an electrode finger or a dummy electrode of a first IDT electrode and an adjacent electrode finger or an adjacent dummy electrode of a fourth comb-shaped electrode, which is a floating electrode that is not connected to any of an input terminal, output terminals, and a ground terminal, is longer than a distance between the electrode finger or the dummy electrode of the first IDT electrode and an adjacent electrode finger or an adjacent dummy electrode of a third comb-shaped electrode, which is connected to the input terminal, the output terminal, or the ground terminal.

### BACKGROUND OF THE INVENTION

1. Field of the Invention

The present invention relates to an elastic wave filter.

2. Description of the Related Art

In recent years, elastic wave filters utilizing elastic waves, such as surface acoustic waves or boundary acoustic waves, have been widely used as filters for mobile phones. An example of such elastic wave filters is described in Japanese Unexamined Patent Application Publication No. 2009-38718. FIG. 11 illustrates a schematic plan view of an elastic wave filter described in Japanese Unexamined Patent Application Publication No. 2009-38718. FIG. 12 illustrates a schematic plan view of a portion of the elastic wave filter described in Japanese Unexamined Patent Application Publication No. 2009-38718. In FIG. 11, interdigital transducer (IDT) electrodes and reflectors are schematically illustrated. The number of electrode fingers illustrated therein is smaller than the actual number.

As illustrated in FIG. 11, an elastic wave filter 100 includes first to third IDT electrodes 101 to 103 that are arranged along a propagation direction of elastic waves. One-side comb-shaped electrodes of the first and third IDT electrodes 101 and 103 are connected to an input terminal 104. The other-side comb-shaped electrodes are each connected to a ground terminal. The second IDT electrode 102 includes two divided IDT electrode sections that are arranged along the propagation direction of elastic waves. One-side comb-shaped electrodes 102a and 102b of the two divided IDT electrode sections are each connected to a first or second output terminal 105a or 105b. The other-side comb-shaped electrode 102c is a floating electrode that is not connected to a signal terminal, a ground electrode, or the like.

FIG. 12 illustrates a schematic plan view in which a portion of the second and third IDT electrodes 102 and 103 is enlarged. As illustrated in FIG. 12, an outermost electrode finger of the second IDT electrode 102, which is located on the third IDT electrode 103 side, is an electrode finger 102c1 of the comb-shaped electrode 102c which is the floating electrode. Among a plurality of electrode fingers of the comb-shaped electrode 102c, electrode fingers, other than the outermost electrode finger 102c1 located on the third IDT electrode 103 side, face dummy electrode fingers of the comb-shaped electrodes 102a and 102b in an intersecting width direction.

In contrast, the electrode finger 102c1 does not face a dummy electrode finger of the comb-shaped electrode 102b in the intersecting width direction. A region where the electrode finger 102c1 is provided, in the propagation direction of elastic waves, is also not provided with a busbar of the comb-shaped electrode 102b. This configuration can increase the distance between the busbar of the comb-shaped electrode 102b and a busbar of the other-side comb-shaped electrode of the third IDT electrode 103. Japanese Unexamined Patent Application Publication No. 2009-38718 describes that damage of the IDT second electrode 102 and the third IDT electrode 103 caused by electro-static discharge (ESD) can therefore be suppressed.

However, in the elastic wave filter described Japanese Unexamined Patent Application Publication No. 2009-38718, damage of the IDT electrodes caused by ESD cannot be sufficiently suppressed. Specifically, in the elastic wave filter described in Japanese Unexamined Patent Application Publication No. 2009-38718, the IDT electrodes are susceptible to damage from ESD during the manufacturing process.

### SUMMARY OF THE INVENTION

In view of the above-described problems, preferred embodiments of the present invention provide an elastic wave filter in which damage caused by ESD is much less likely to occur.

A first elastic wave filter according to a preferred embodiment of the present invention includes an input terminal, output terminals, and an elastic wave filter unit. The elastic wave filter unit is connected between the input and output terminals. The elastic wave filter unit includes a piezoelectric substrate, a first IDT electrode, and a second IDT electrode. The first IDT electrode is located on the piezoelectric substrate. The first IDT electrode includes first and second comb-shaped electrodes. The first and second comb-shaped electrodes are interdigitated with each other. The second IDT electrode is disposed on the piezoelectric substrate on one side of the first IDT electrode in a propagation direction of elastic waves. The second IDT electrode includes third and fourth comb-shaped electrodes. The third and fourth comb-shaped electrodes are interdigitated with each other. The first to third comb-shaped electrodes are each connected to the input terminal, the output terminals, or a ground terminal. The fourth comb-shaped electrode is a floating electrode that is not connected to any of the input terminal, the output terminals, and the ground terminal. The first to fourth comb-shaped electrodes each include a busbar, a plurality of electrode fingers, and a plurality of dummy electrodes. The plurality of electrode fingers are connected to the busbar. The plurality of dummy electrodes are connected to the busbar. The plurality of dummy electrodes face the plurality of electrode fingers of each interdigitated comb-shaped electrode, respectively, in an intersecting width direction. The distance between an electrode finger or a dummy electrode of the first IDT electrode and an adjacent electrode finger or an adjacent dummy electrode of the fourth comb-shaped electrode is longer than the distance between the electrode finger or the dummy electrode of the first IDT electrode and an adjacent electrode finger or an adjacent dummy electrode of the third comb-shaped electrode.

In a certain aspect of the first elastic wave filter according to a preferred embodiment of the present invention, an outermost electrode finger located on the first IDT electrode side, among the plurality of electrode fingers of the third and fourth comb-shaped electrodes, is an electrode finger of the third comb-shaped electrode. The fourth comb-shaped electrode is not provided with a dummy electrode facing the outermost electrode finger located on the first IDT electrode side in the intersecting width direction.

In another certain aspect of the first elastic wave filter according to a preferred embodiment of the present invention, an end portion of the busbar on the first IDT electrode side, of the fourth comb-shaped electrode, is located on the other side of the propagation direction of elastic waves with respect to the outermost electrode finger located on the first IDT electrode side.

In another certain aspect of the first elastic wave filter according to a preferred embodiment of the present invention, at least one of the busbar of the fourth comb-shaped electrode and the busbar of one of the first and second comb-shaped electrodes, which is disposed on the same side as the fourth comb-shaped electrode in the intersecting width direction, includes a protruding portion. The protruding portion faces a portion or a protruding portion of the other busbar.

In still another certain aspect of the first elastic wave filter according to a preferred embodiment of the present invention, the distance between the portions facing each other is shorter than the distance between the electrode finger or the dummy electrode of the first IDT electrode and the adjacent electrode finger or the adjacent dummy electrode of the fourth comb-shaped electrode.

A second elastic wave filter according to a preferred embodiment of the present invention includes an input terminal, output terminals, and an elastic wave filter unit connected between the input and output terminals. The elastic wave filter unit includes a piezoelectric substrate, a first IDT electrode, and a second IDT electrode. The first IDT electrode is located on the piezoelectric substrate. The first IDT electrode includes first and second comb-shaped electrodes. The first and second comb-shaped electrodes are each connected to the input terminal, the output terminals, or a ground terminal. The first and second comb-shaped electrodes are interdigitated with each other. The second IDT electrode is disposed on the piezoelectric substrate on one side of the first IDT electrode in a propagation direction of elastic waves. The second IDT electrode includes third and fourth comb-shaped electrodes interdigitated with each other. The first to third comb-shaped electrodes are each connected to the input terminal, the output terminals, or the ground terminal. The fourth comb-shaped electrode is a floating electrode that is not connected to any of the input terminal, the output terminals, and the ground terminal. The first to fourth comb-shaped electrodes each include a busbar, a plurality of electrode fingers, and a plurality of dummy electrodes. The plurality of electrode fingers are connected to the busbar. The plurality of dummy electrodes are connected to the busbar. The plurality of dummy electrodes face the plurality of electrode fingers of each interdigitated comb-shaped electrode, respectively, in an intersecting width direction. At least one of the busbar of the fourth comb-shaped electrode and the busbar of one of the first and second comb-shaped electrodes, which is disposed on the same side as the fourth comb-shaped electrode in the intersecting width direction, includes a protruding portion. The protruding portion faces a portion or a protruding portion of the other busbar in the intersecting width direction.

In still another certain aspect of each of the first and second elastic wave filters according to various preferred embodiments of the present invention, the piezoelectric substrate is preferably made of LiNbO₃, LiTaO₃ or quartz, for example.

In still another certain aspect of each of the first and second elastic wave filters according to various preferred embodiments of the present invention, the elastic wave filter is a surface acoustic wave filter or a boundary acoustic wave filter.

In a first elastic wave filter according to a preferred embodiment of the present invention, the distance between an electrode finger or a dummy electrode of a first IDT electrode and an adjacent electrode finger or an adjacent dummy electrode of a fourth comb-shaped electrode is longer than the distance between the electrode finger or the dummy electrode of the first IDT electrode and an adjacent electrode finger or an adjacent dummy electrode of a third comb-shaped electrode. Damage caused by ESD can therefore be significantly reduced and prevented.

In a second elastic wave filter according to a preferred embodiment of the present invention, at least one of a busbar of a fourth comb-shaped electrode and a busbar of one of first and second comb-shaped electrodes, which is disposed on the same side as the fourth comb-shaped electrode in an intersecting width direction, includes a protruding portion. The protruding portion faces a portion or a protruding portion of the other busbar in the intersecting width direction. Damage caused by ESD can therefore be significantly reduced and prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of an elastic wave filter according to a first preferred embodiment of the present invention.

FIG. 2 is a schematic plan view in which a portion of the elastic wave filter according to the first preferred embodiment of the present invention is enlarged.

FIG. 3 is a schematic cross-sectional view of the elastic wave filter according to the first preferred embodiment of the present invention.

FIG. 4 is a schematic plan view of an elastic wave filter according to a first comparative example.

FIG. 5 is a schematic plan view in which a portion of the elastic wave filter according to the first comparative example is enlarged.

FIG. 6 is a schematic plan view of an elastic wave filter according to a second comparative example.

FIG. 7 is a graph illustrating insertion losses of respective surface acoustic wave filters according to the first preferred embodiment of the present invention and the first and second comparative examples.

FIG. 8 is a schematic plan view in which a portion of an elastic wave filter according to a second preferred embodiment of the present invention is enlarged.

FIG. 9 is data illustrating incidences of destructive failures caused by ESD in respective surface acoustic wave filters in first to third examples of a preferred embodiment of the present invention and the first comparative example.

FIG. 10 is a schematic cross-sectional view of an elastic wave filter according to a modification of a preferred embodiment of the present invention.

FIG. 11 is a schematic plan view of an elastic wave filter described in Japanese Unexamined Patent Application Publication No. 2009-38718.

FIG. 12 is a schematic plan view of a portion of the elastic wave filter described in Japanese Unexamined Patent Application Publication No. 2009-38718.

### DETAILED DESCRIPTION OF THE PREFERRED EMBODIMENTS

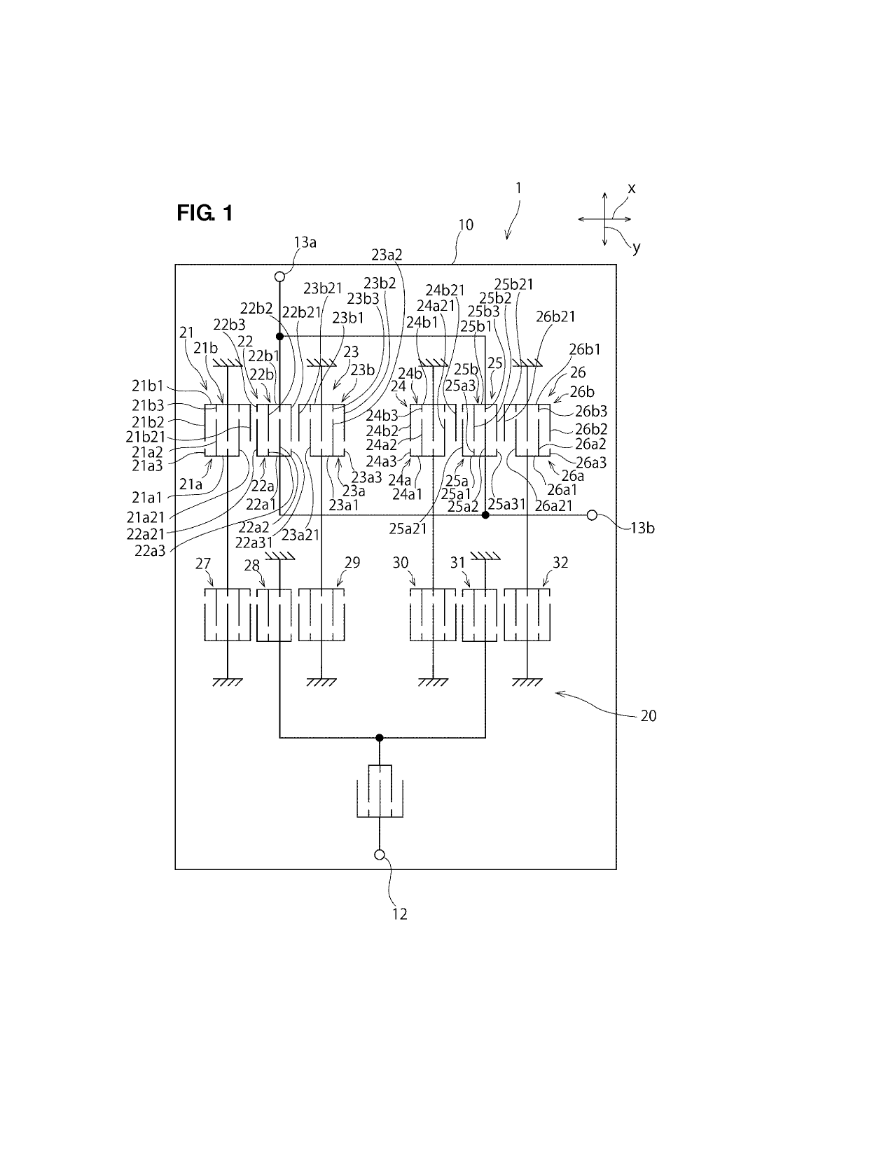

A preferred embodiment of the present invention will be described below taking, as a non-limiting example, a surface acoustic wave filter 1 illustrated in FIG. 1. Note that the surface acoustic wave filter 1 is merely an example. The present invention is not limited to the surface acoustic wave filter 1.

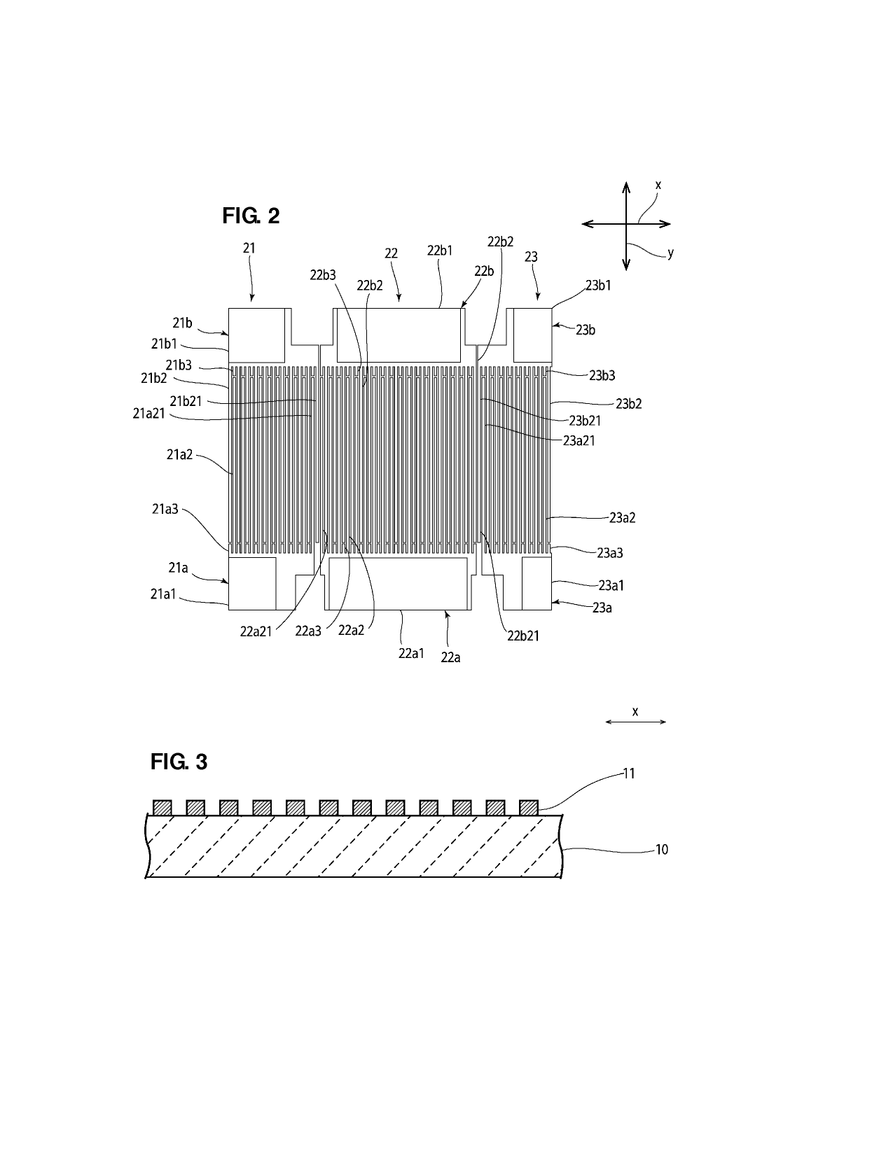

FIG. 1 is a schematic plan view of an elastic wave filter according to the present preferred embodiment. FIG. 2 is a schematic plan view in which a portion of the elastic wave filter according to the present preferred embodiment is enlarged. FIG. 3 is a schematic cross-sectional view of the elastic wave filter according to the present preferred embodiment. A configuration of the surface acoustic wave filter 1 of the present preferred embodiment will be described with reference to FIGS. 1 to 3.

The surface acoustic wave filter 1 is a so-called balanced-type surface acoustic wave filter having a balanced-unbalanced transforming function. As illustrated in FIG. 1, the surface acoustic wave filter 1 includes an unbalanced input terminal 12 and balanced output terminals 13a and 13b. A surface acoustic wave filter unit 20 is connected between the unbalanced input terminal 12 and the balanced output terminals 13a and 13b.

The surface acoustic wave filter unit 20 includes a piezoelectric substrate 10, a plurality of IDT electrodes 21 to 32 and a plurality of reflectors (not illustrated) located on the piezoelectric substrate 10. The plurality of IDT electrodes 21 to 32, the plurality of reflectors, various types of wirings and the like are constituted by an electrode 11 (see FIG. 3) located on the piezoelectric substrate 10. The electrode 11 may include a metal selected from a group consisting of Al, Pt, Au, Ag, Cu, Ni, Ti, Cr, and Pd, or an alloy containing at least one metal selected from a group consisting of Al, Pt, Au, Ag, Cu, Ni, Ti Cr, and Pd. The electrode 11 may be constituted by a laminate including a plurality of conductive layers composed of the metal or the alloy.

In the present preferred embodiment, the piezoelectric substrate 10 has pyroelectricity in addition to piezoelectricity. The piezoelectric substrate 10 can be composed of, for example, LiNbO₃, LiTaO₃ or quartz.

The IDT electrodes 21 to 23, the IDT electrodes 24 to 26, the IDT electrodes 27 to 29, and the IDT electrodes 30 to 32 are each arranged, in sequence, along a propagation direction x of surface acoustic waves. A pair of the plurality of reflectors, whose illustration is omitted, are disposed on the respective sides of a region where the IDT electrodes 21 to 23, the IDT electrodes 24 to 26, the IDT electrodes 27 to 29, and the IDT electrodes 30 to 32 are each provided, in the propagation direction x of surface acoustic waves. The IDT electrodes 21 to 32 each include a pair of comb-shaped electrodes interdigitated with each other.

One-side comb-shaped electrodes of the IDT electrodes 28 and 31 are connected to the unbalanced input terminal 12. The other-side comb-shaped electrodes of the IDT electrodes 28 and 31 are each connected to a ground terminal. One-side comb-shaped electrodes of the IDT electrodes 27, 29, 30, and 32, which are located on the respective sides of the IDT electrodes 28 and 31 in the propagation direction x of surface acoustic waves, are each connected to a ground terminal. The other-side comb-shaped electrodes of the IDT electrodes 27, 29, 30, and 32 are connected to one-side comb-shaped electrodes 21a, 23a, 24a, and 26a of the IDT electrodes 21, 23, 24, and 26, respectively.

The other-side comb-shaped electrodes 21b, 23b, 24b, and 26b of the IDT electrodes 21, 23, 24, and 26 are each connected to a ground terminal. One-side comb-shaped electrodes 22a and 25a of the IDT electrodes 22 and 25, which are located between the IDT electrodes 21 and 23 and between the IDT electrodes 24 and 26, respectively, in the propagation direction x of surface acoustic waves, are connected to the balanced output terminal 13b. The other-side comb-shaped electrodes 22b and 25b are connected to the balanced output terminal 13a.

The comb-shaped electrodes 21a, 23a, 24a, and 26a among the comb-shaped electrodes 21a to 26a and 21b to 26b of the IDT electrodes 21 to 26 are floating electrodes that are not connected to any of the unbalanced input terminal 12, the balanced output terminals 13a and 13b, and the ground terminal. The other comb-shaped electrodes 21b, 22a, 22b, 23b, 24b, 25a, 25b, and 26b are each connected to the unbalanced input terminal 12, the balanced output terminal 13a or 13b, or the ground terminal.

The comb-shaped electrodes 21a to 26a and 21b to 26b include busbars 21a1 to 26a1 and 21b1 to 26b1, electrode fingers 21a2 to 26a2 and 21b2 to 26b2, and dummy electrodes 21a3 to 26a3 and 21b3 to 26b3, respectively. The electrode fingers 21a2 to 26a2 and 21b2 to 26b2 and the dummy electrodes 21a3 to 26a3 and 21b3 to 26b3 extend from the busbars 21a1 to 26a1 and 21b1 to 26b1, respectively, along an intersecting width direction y perpendicular to the propagation direction x of surface acoustic waves. The dummy electrodes 21a3 to 26a3 and 21b3 to 26b3 face the electrode fingers 21b2 to 26b2 and 21a2 to 26a2 of the comb-shaped electrodes interdigitated with the comb-shaped electrodes to which the dummy electrodes 21a3 to 26a3 and 21b3 to 26b3 belong, respectively, in the intersecting width direction y.

As illustrated in FIGS. 1 to 3, in the present preferred embodiment, in the respective IDT electrodes 21, 23, 24, and 26, outermost electrode fingers located on the IDT electrode side or the IDT electrode 25 side, among the plurality of electrode fingers 21a2, 21b2, 23a2, 23b2, 24a2, 24b2, 26a2, and 26b2, are electrode fingers 21b21, 23b21, 24b21, and 26b21 belonging to the respective comb-shaped electrodes 21b, 23b, 24b, and 26b, which are not the floating electrodes. The comb-shaped electrodes 21a, 23a, 24a, and 26a, which are the floating electrodes, are not provided with dummy electrodes facing the electrode fingers 21b21, 23b21, 24b21, and 26b21 in the intersecting width direction y. Thus, the distance between the electrode finger 21a2 or the dummy electrode 21a3 of the comb-shaped electrode 21a, which is the floating electrode, and the adjacent electrode finger 22a2 or 22b2 or the adjacent dummy electrode 22a3 or 22b3 of the IDT electrode 22, in the propagation direction x of surface acoustic waves, is longer than the distance between the electrode finger 21b2 or the dummy electrode 21b3 of the comb-shaped electrode 21b and the adjacent electrode finger 22a2 or 22b2 or the adjacent dummy electrode 22a3 or 22b3 of the IDT electrode 22, in the propagation direction x of surface acoustic waves. Specifically, in the propagation direction x of surface acoustic waves, the distance between an outermost electrode finger 21a21 located on the IDT electrode 22 side, among the electrode finger 21a2 and the dummy electrode 21a3 of the comb-shaped electrode 21a, which is the floating electrode, and an outermost electrode finger 22a21 located on the IDT electrode 21 side, among the electrode fingers 22a2 and 22b2 and the dummy electrodes 22a3 and 22b3 of the IDT electrode 22, is longer than the distance between the outermost electrode finger 21b21 located on the IDT electrode 22 side, among the electrode finger 21b2 and the dummy electrode 21b3 of the comb-shaped electrode 21b, and the electrode finger 22a21.

Similarly, in the propagation direction x of surface acoustic waves, the distance between an outermost electrode finger 23a21 located on the IDT electrode 22 side, among the electrode finger 23a2 and the dummy electrode 23a3 of the comb-shaped electrode 23a, which is the floating electrode, and an outermost dummy electrode 22a31 located on the IDT electrode 23 side, among the electrode fingers 22a2 and 22b2 and the dummy electrodes 22a3 and 22b3 of the IDT electrode 22, is longer than the distance between the outermost electrode finger 23b21 located on the IDT electrode 22 side, among the electrode finger 23b2 and the dummy electrode 23b3 of the comb-shaped electrode 23b, and an electrode finger 22b21.

In the propagation direction x of surface acoustic waves, the distance between an outermost electrode finger 24a21 located on the IDT electrode 25 side, among the electrode finger 24a2 and the dummy electrode 24a3 of the comb-shaped electrode 24a, which is the floating electrode, and an outermost electrode finger 25a21 located on the IDT electrode 24 side, among the electrode fingers 25a2 and 25b2 and the dummy electrodes 25a3 and 25b3 of the IDT electrode 25, is longer than the distance between the outermost electrode finger 24b21 located on the IDT electrode 25 side, among the electrode finger 24b2 and the dummy electrode 24b3 of the comb-shaped electrode 24b, and the electrode finger 25a21.

In the propagation direction x of surface acoustic waves, the distance between an outermost electrode finger 26a21 located on the IDT electrode 25 side, among the electrode finger 26a2 and the dummy electrode 26a3 of the comb-shaped electrode 26a, which is the floating electrode, and an outermost dummy electrode 25a31 located on the IDT electrode 26 side, among the electrode fingers 25a2 and 25b2 and the dummy electrodes 25a3 and 25b3 of the IDT electrode 25, is longer than the distance between the outermost electrode finger 26b21 located on the IDT electrode 25 side, among the electrode finger 26b2 and the dummy electrode 26b3 of the comb-shaped electrode 26b, and an electrode finger 25b21.

End portions of the busbars 21a1 and 23a1 on the IDT electrode 22 side, of the corresponding comb-shaped electrodes 21a and 23a, which are the floating electrodes, are respectively located farther from the IDT electrode 22 than the electrode fingers 21b21 and 23b21 are, and end portions of the busbars 24a1 and 26a1 on the IDT electrode 25 side, of the corresponding comb-shaped electrodes 24a and 26a, which are the floating electrodes, are respectively located farther from the IDT electrode 25 than the electrode fingers 24b21 and 26b21 are. Specifically, in the propagation direction x of surface acoustic waves, the distance between each of the busbars 21a1 and 23a1 and the IDT electrode 22 and the distance between each of the busbars 24a1 and 26a1 and the IDT electrode 25 are each preferably about 1.5 times the wavelength of a surface acoustic wave, for example.

In the present preferred embodiment, because the comb-shaped electrodes 21a, 23a, 24a, and 26a, which are the floating electrodes, are not provided with dummy electrodes facing the electrode fingers 21b21, 23b21, 24b21, and 26b21 in the intersecting width direction y, the distance between each of the comb-shaped electrodes 21a, 23a, 24a, and 26a and the IDT electrode 22 or 25 is increased. However, the present invention is not limited to this configuration. In order to increase the distance between each of the comb-shaped electrodes, which are the floating electrodes, and the adjacent IDT electrode, the adjacent IDT electrode may include a comb-shaped electrode that is not provided with such a dummy electrode. That is, in the IDT electrode adjacent to the comb-shaped electrode, which is the floating electrode, a dummy electrode facing an outermost electrode finger located on the floating electrode side in the intersecting width direction y is not provided. Such a configuration can also increase the distance between the floating electrode and the adjacent IDT electrode.

In the present preferred embodiment, the surface acoustic wave filter 1 having a balanced-unbalanced transforming function is preferably used, for example. However, the present invention can also be accomplished using a surface acoustic wave filter without a balanced-unbalanced transforming function. That is, in the present preferred embodiment, the comb-shaped electrodes 22a and 25a are preferably connected to the balanced output terminal 13b, for example. However, the comb-shaped electrodes 22a and 25a may be connected to a ground terminal.

In the present preferred embodiment, the present invention is accomplished preferably using the IDT electrodes 21 to 26, but may be accomplished using the IDT electrodes 27 to 32. Consequently, ESD damage is much less likely to occur.

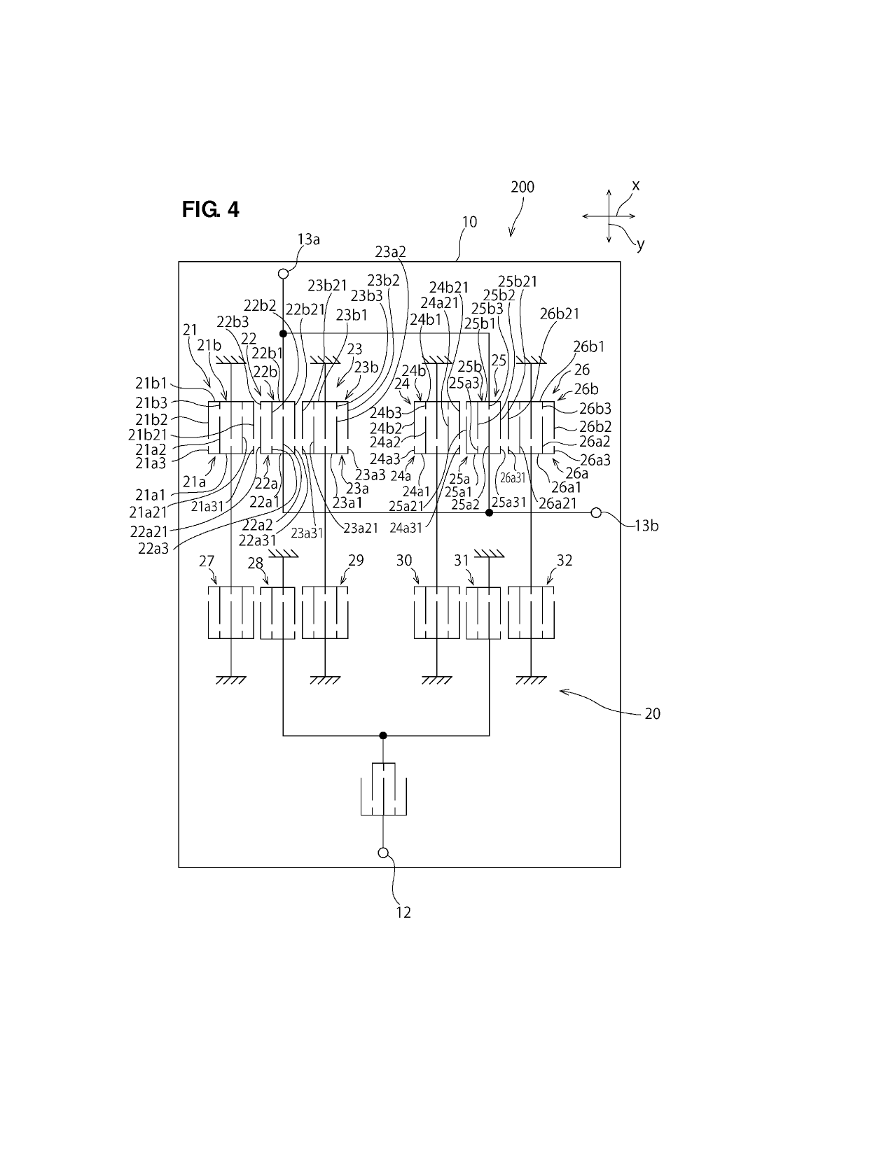

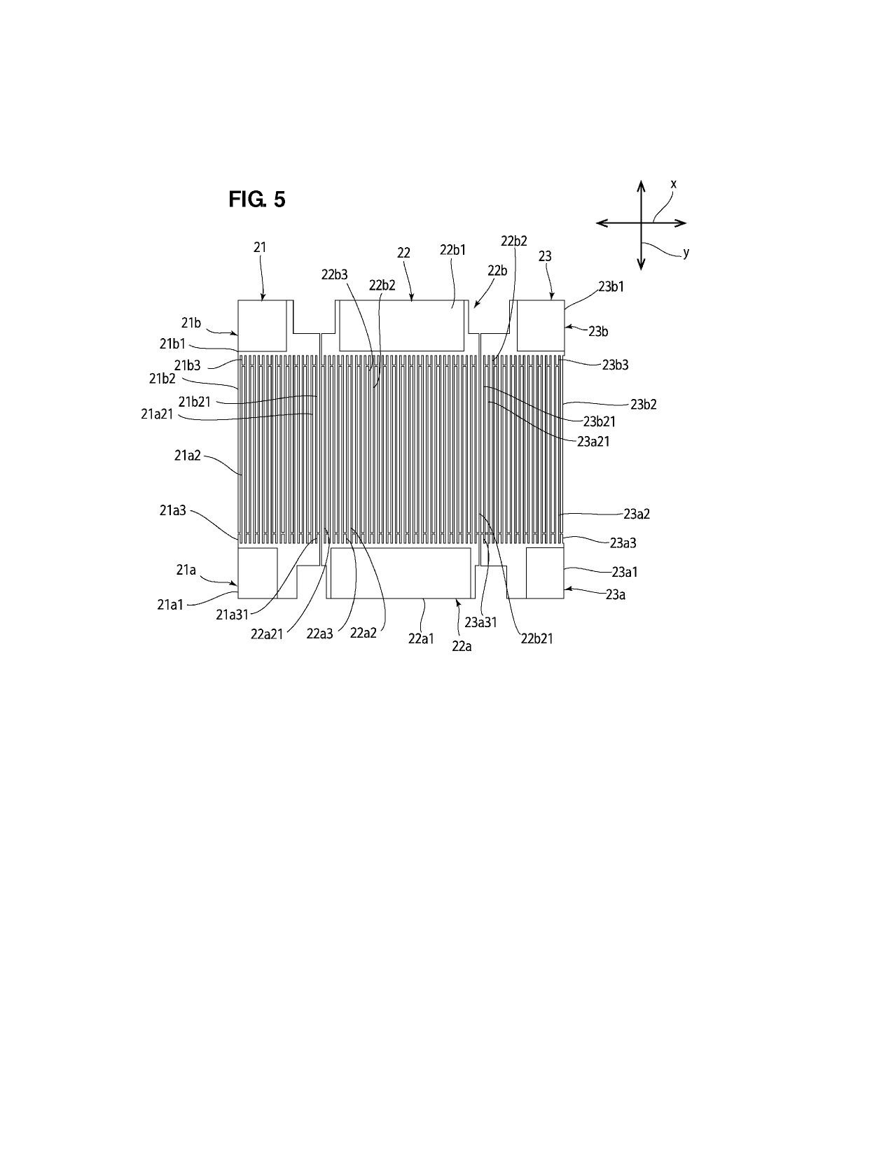

FIG. 4 is a schematic plan view of a surface acoustic wave filter 200 according to a first comparative example. FIG. 5 is a schematic plan view in which a portion of the surface acoustic wave filter 200 according to the first comparative example is enlarged. In the first comparative example illustrated in FIGS. 4 and 5, components having substantially the same functions as those of the first preferred embodiment described above are designated by the same reference numerals, and description thereof is omitted.

As illustrated in FIGS. 4 and 5, comb-shaped electrodes 21a, 23a, 24a, and 26a, which are floating electrodes, are typically provided with dummy electrodes 21a31, 23a31, 24a31, and 26a31 facing electrode fingers 21b21, 23b21, 24b21, and 26b21 in an intersecting width direction y, respectively. However, as a result of intensive research conducted by the present inventors, it has been discovered that when the dummy electrodes 21a31, 23a31, 24a31, and 26a31 are provided, damage caused by electro-static discharge (ESD) is likely to occur, for example, in the process of manufacturing the surface acoustic wave filter 200. The reason will be described in detail below.

A piezoelectric substrate 10 has pyroelectricity. Accordingly, for example, in the manufacturing process, a change in the temperature of the piezoelectric substrate 10 generates electric charges. In view of the foregoing, it is ideal to prevent the temperature of the piezoelectric substrate 10 from changing during the manufacturing process. However, for example, during peeling of surface acoustic wave filter chips, which are separated by dicing, from a dicing film by heating, the piezoelectric substrate 10 is heated. Actually, this makes it difficult to ensure that the change in the temperature of the piezoelectric substrate 10 is controlled, during the manufacturing process.

Thus, it is difficult to avoid generation of electric charges in the piezoelectric substrate 10. In the manufacturing process, when terminal electrodes are in a non-contact state, electric charges are uniformly generated in the entire piezoelectric substrate 10. A potential difference is therefore not generated between adjacent electrodes. On the other hand, when terminal electrodes are in a contact state, electric charges generated in the piezoelectric substrate 10 are immediately diffused. Accordingly, a potential difference is also not generated between adjacent electrodes. As a result, in the manufacturing process, ESD damage does not occur as long as terminal electrodes are maintained in such a non-contact or contact state.

However, in the actual manufacturing process, terminal electrodes are alternately in contact and non-contact states. For example, after electric charges generated in such a non-contact state have accumulated in each electrode, when terminal electrodes are in such a contact state, the electric potentials of electrodes, which are each connected to a terminal, significantly decrease. On the other hand, the electric potentials of floating electrodes, which are each not connected to a terminal, are maintained. A potential difference is therefore generated between each floating electrode and an electrode, which is adjacent to the floating electrode and is connected to a terminal. As a result, ESD damage occurs at a position between both electrodes. Accordingly, ESD damage originates from the floating electrode.

Thus, for example, in the surface acoustic wave filter 200 according to the first comparative example illustrated in FIGS. 4 and 5, ESD damage occurs at a position between, for example, the dummy electrode 21a31 and the electrode finger 22a21.

Furthermore, in the elastic wave filter 100 described in Japanese Unexamined Patent Application Publication No. 2009-38718, because the electrode finger 102c1 of the comb-shaped electrode 102c, which is a floating electrode, is adjacent to an electrode finger of the third IDT electrode 103, ESD damage occurs at a position between the electrode finger 102c1 and the electrode finger of the third IDT electrode 103 adjacent to the electrode finger 102c1.

In contrast, in the present preferred embodiment, the comb-shaped electrodes 21a, 23a, 24a, and 26a, which are floating electrodes, are not provided with the dummy electrodes 21a31, 23a31, 24a31, and 26a31. As a result, the distance between the electrode fingers 21a21 and 22a21 is longer than the distance between the electrode fingers 21b21 and 22a21. The distance between the electrode finger 23a21 and the dummy electrode 22a31 is longer than the distance between the electrode fingers 23b21 and 22b21. The distance between the electrode fingers 24a21 and 25a21 is longer than the distance between the electrode fingers 24b21 and 25a21. The distance between the electrode finger 26a21 and the dummy electrode 25a31 is longer than the distance between the electrode fingers 26b21 and 25b21.

Thus, the distance between the electrode finger or the dummy electrode of each of the comb-shaped electrodes 21a, 23a, 24a, and 26a, which are the floating electrodes, and the electrode finger or the dummy electrode of each of the IDT electrodes 22 and 25 is long. Accordingly, ESD damage is less likely to occur.

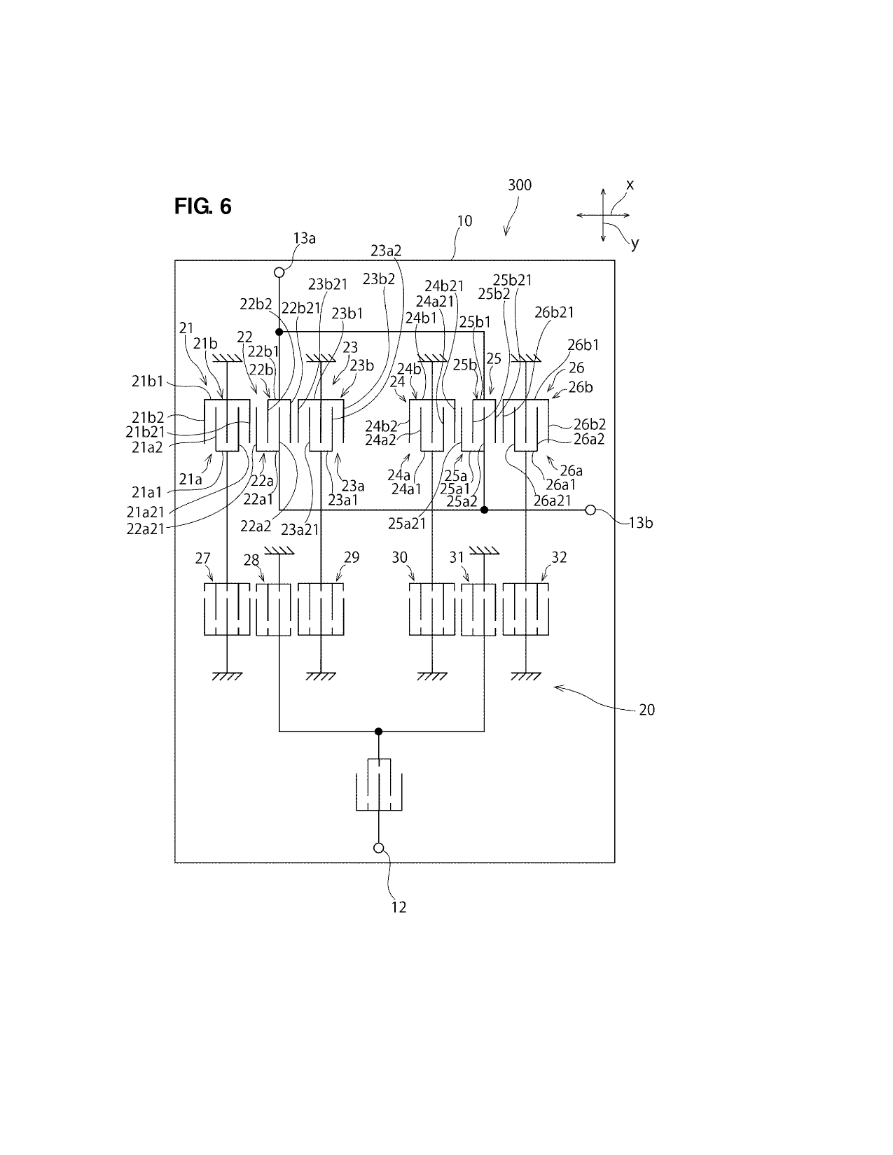

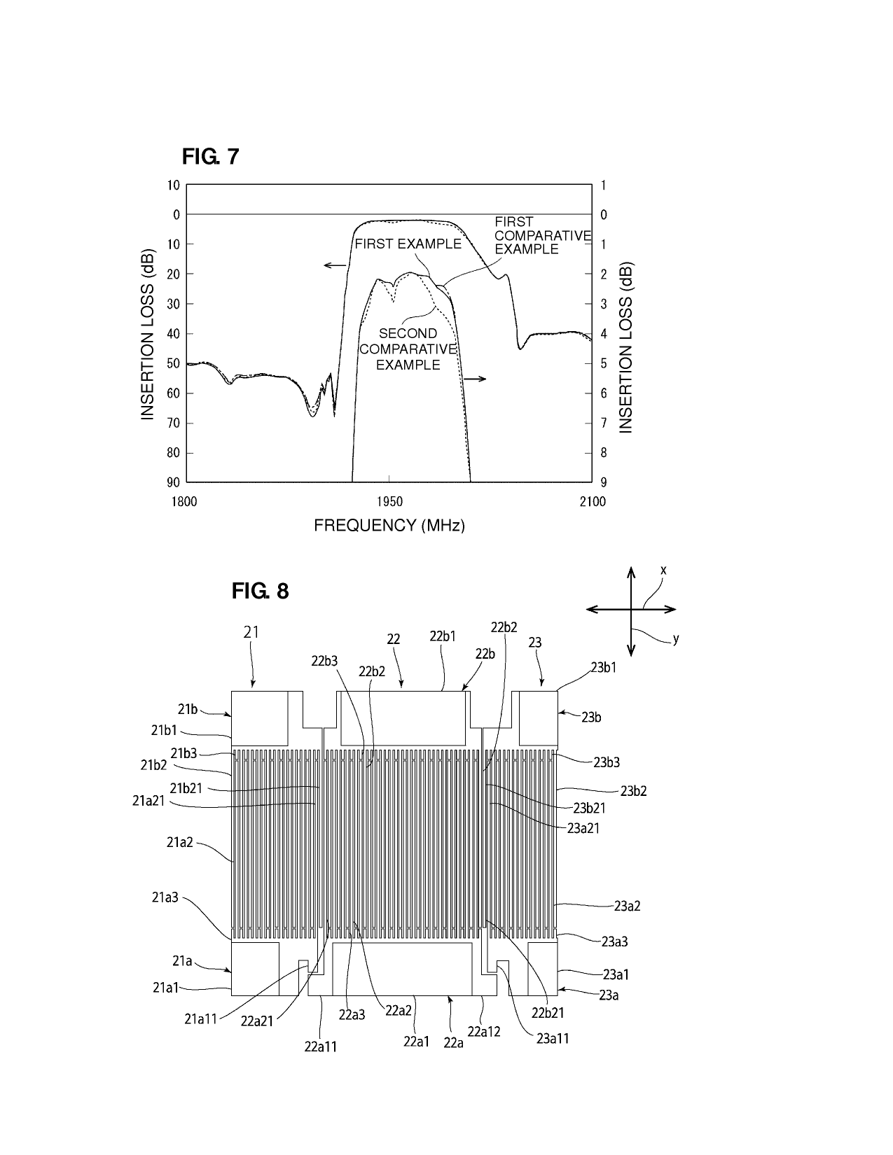

In the present preferred embodiment, because resistance to ESD damage is improved only by not providing the dummy electrodes 21a31, 23a31, 24a31, and 26a31, deterioration of characteristics of the surface acoustic wave filter 1 is minimized. If considering only resistance to ESD damage, the distance between IDT electrodes adjacent to each other may be increased by providing no dummy electrodes. However, if no dummy electrodes are provided, the uniformity of transmission characteristics deteriorates. Actually, the surface acoustic wave filter 1 of the first preferred embodiment and the surface acoustic wave filter 200 of the first comparative example were fabricated according to substantially the same design parameters, and then insertion losses thereof were measured. As illustrated in FIG. 6, a surface acoustic wave filter 300 of a second comparative example, which is not provided with dummy electrodes 21a3 to 26a3 and 21b3 to 26b3, was fabricated according to substantially the same design parameters as those of the surface acoustic wave filter 1 of the first preferred embodiment, and then insertion losses thereof were measured. FIG. 7 illustrates the results. It is understood from the results illustrated in FIG. 7 that the surface acoustic wave filter 1 of the first preferred embodiment has the uniformity of transmission characteristics equal to that of the surface acoustic wave filter 200. On the other hand, it is understood that, in the surface acoustic wave filter 300 of the second comparative example, which is provided with no dummy electrodes, insertion loss in a pass band deteriorates significantly.

In the first preferred embodiment, the end portions of the busbars 21a1 and 23a1 on the IDT electrode 22 side, of the corresponding comb-shaped electrodes 21a and 23a, which are the floating electrodes, are respectively located farther from the IDT electrode 22 than the electrode fingers 21b21 and 23b21 are, and the end portions of the busbars 24a1 and 26a1 on the IDT electrode 25 side, of the corresponding comb-shaped electrodes 24a and 26a, which are the floating electrodes, are respectively located farther from the IDT electrode 25 than the electrode fingers 24b21 and 26b21 are. Accordingly, ESD damage is less likely to occur also at a position between each of the busbars 21a1 and 23a1 and the busbar 22a1, and between each of the busbars 24a1 and 26a1 and the busbar 25a1.

Other examples and a modification of the first preferred embodiment of the present invention will be described below. In the following description, components having substantially the same functions as those of the first preferred embodiment are designated by the same reference numerals, and description thereof is omitted.

### Second Preferred Embodiment

FIG. 8 is a schematic plan view in which a portion of an elastic wave filter according to a second preferred embodiment is enlarged. In the second preferred embodiment, FIG. 1 of the first preferred embodiment is also referred to.

As illustrated in FIG. 8, in the second preferred embodiment of the present invention, busbars 21a1 and 22a1 include rectangular-shaped or substantially rectangular-shaped protruding portions 21a11 and 22a11 facing each other in an intersecting width direction y, respectively. Busbars 22a1 and 23a1 include protruding portions 22a12 and 23a11 facing each other in the intersecting width direction y, respectively. The distance between the protruding portions 21a11 and 22a11 and the distance between the protruding portions 22a12 and 23a11 are each shorter than the distance between electrode fingers 21a21 and 22a21. Accordingly, if ESD damage should occur, the damage will occur at a position between the protruding portions 21a11 and 22a11 and/or between the protruding portions 22a12 and 23a11. Electrode fingers of IDT electrodes 21 to 32 are therefore not damaged. Consequently, functions of the surface acoustic wave filter are less likely to be lost due to ESD damage.

In the second preferred embodiment, busbars 24a1, 25a1, and 26a1 are similarly provided with protruding portions. If such protruding portions are provided between all of adjacent busbars, resistance to ESD damage is improved. However, the more protruding portions there are, the larger the area of a piezoelectric substrate 10. Accordingly, in the second preferred embodiment, the protruding portions are provided only between the busbars of comb-shaped electrodes, which are floating electrodes, and the busbars of comb-shaped electrodes adjacent to the foregoing comb-shaped electrodes. Consequently, in the second preferred embodiment, the area of the piezoelectric substrate 10 can be reduced more than that of a substrate having busbars which are all provided with protruding portions therebetween.

In the second preferred embodiment, the adjacent busbars are each preferably provided with a protruding portion. However, the protruding portion may be provided in only one of the adjacent busbars to face a portion of the other busbar.

The protruding portion may have not only a rectangular or substantially rectangular shape but also other shapes, such as a triangular or substantially triangular shape. In FIG. 8, dummy electrodes facing electrode fingers 21b21 and 23b21 in the intersecting width direction y are not provided. However, if the distance between protruding portions facing each other is made shorter than that between adjacent busbars, a dummy electrode may be provided.

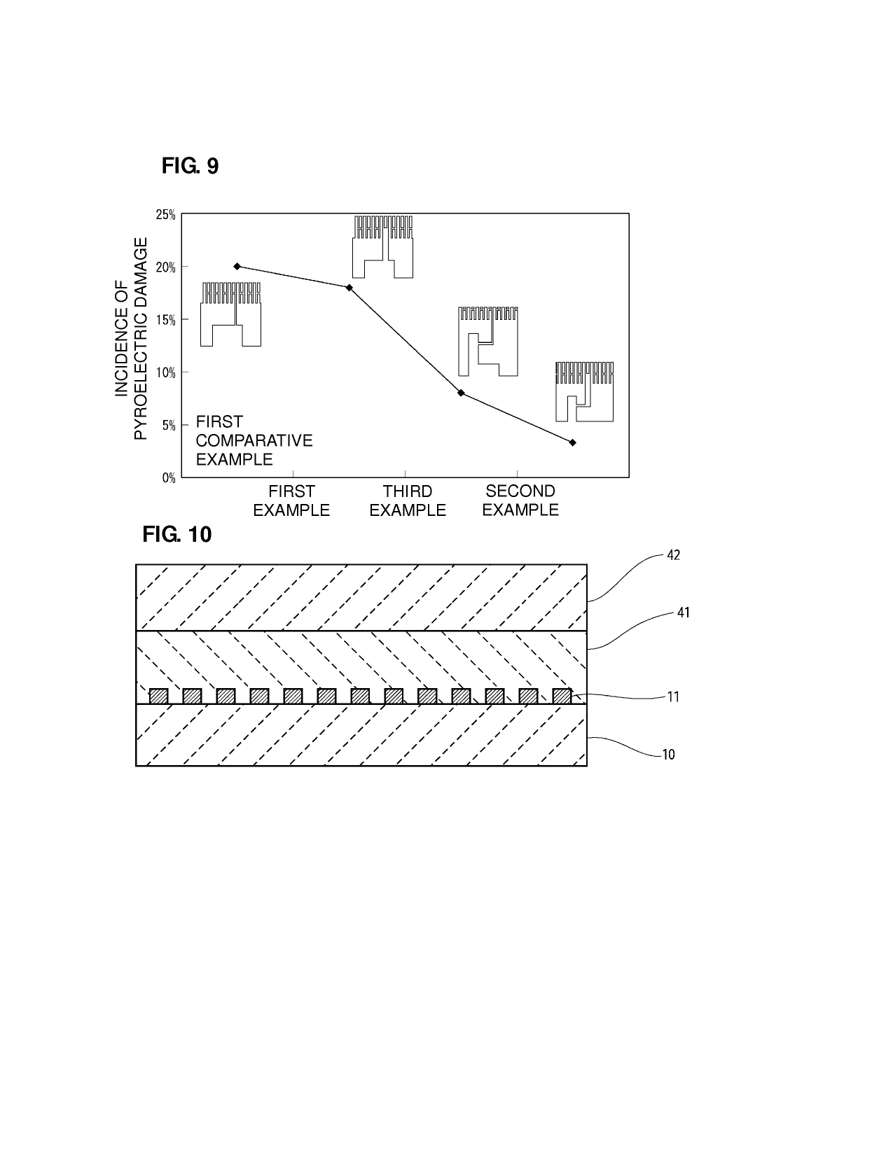

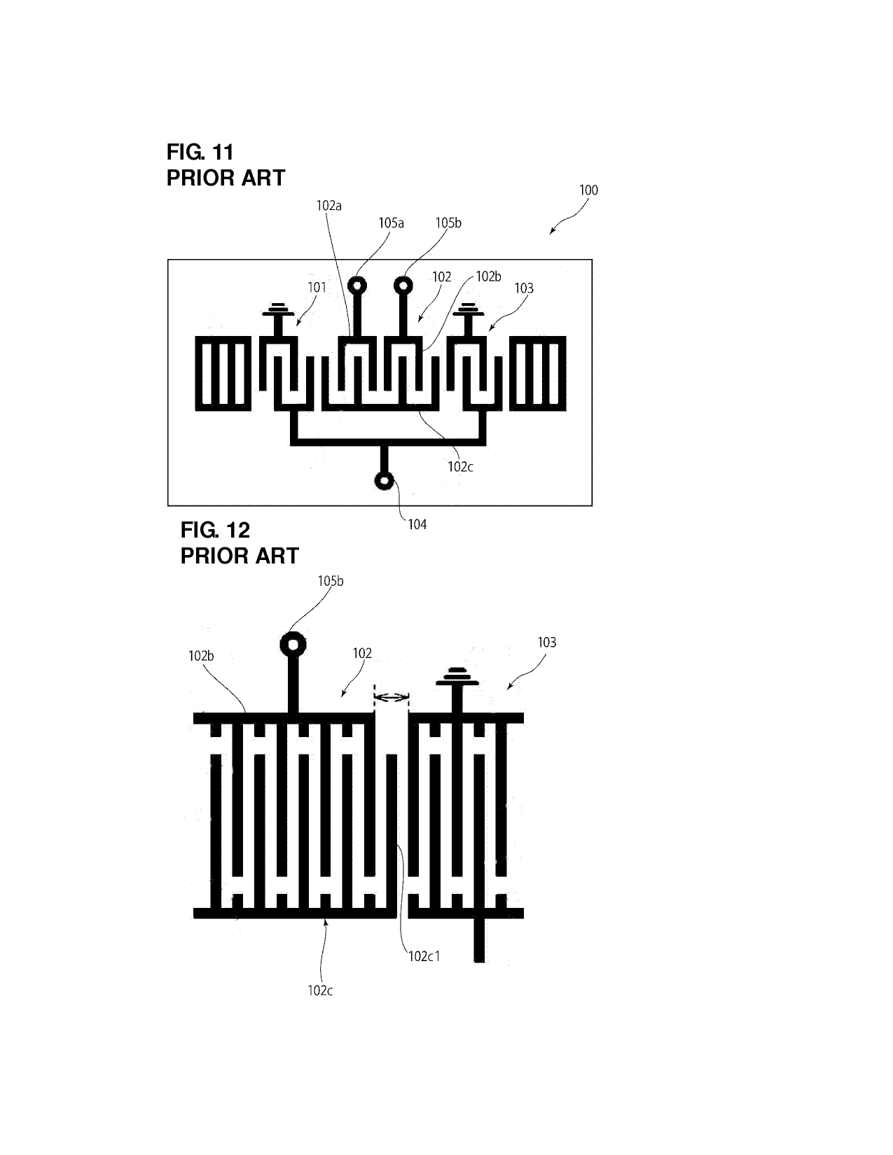

Actually, in a first example, the surface acoustic wave filter 1 of the first preferred embodiment was fabricated. In a second example, a surface acoustic wave filter of the second preferred embodiment, which is not provided with dummy electrodes as illustrated in FIG. 8, was fabricated. In a third example, a surface acoustic wave filter having substantially the same configuration as that of the surface acoustic wave filter of the second preferred embodiment was fabricated, except that dummy electrodes were provided. The surface acoustic wave filters according to the first to third examples and the surface acoustic wave filter according to the first comparative example were each examined for resistance to ESD damage. Specifically, a thermal shock test was performed by applying sixty cycles of thermal shock at a high temperature (85° C. for 30 min) and a low temperature (−40° C. for 30 min) to determine an incidence of a failure due to ESD. FIG. 9 is a graph illustrating the test results. As illustrated in FIG. 9, whereas an incidence of a failure in the first comparative example was 20%, incidences of failures in the first, third and second examples were 18%, 8%, and 3%, respectively.

FIG. 10 is a schematic cross-sectional view of an elastic wave filter according to a modification of a preferred embodiment of the present invention.

In the first preferred embodiment, an example of the elastic wave filter of the present invention is a surface acoustic wave filter 1. However, the elastic wave filter according to the present invention is not limited to the surface acoustic wave filter. As illustrated in FIG. 10, the elastic wave filter according to the present invention may be a so-called three-medium boundary acoustic wave filter that includes first and second dielectric layers 41 and 42 located on a piezoelectric substrate 10. The elastic wave filter may also be a so-called two-medium boundary acoustic wave filter that includes one dielectric layer located on a piezoelectric substrate. The first and second dielectric layers 41 and 42 can be composed of, for example, silicon nitride or silicon oxynitride. The second dielectric layer 42 preferably allows acoustic waves to propagate at a higher velocity than those in the first dielectric layer 41.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave filter comprising:
an input terminal;
an output terminal; and
an elastic wave filter unit connected between the input terminal and the output terminal, the elastic wave filter unit including:
a piezoelectric substrate;
a first IDT electrode located on the piezoelectric substrate, the first IDT electrode including a first comb-shaped electrode and a second comb-shaped electrode interdigitated with each other; and
a second IDT electrode located on the piezoelectric substrate on one side of the first IDT electrode in a propagation direction of elastic waves, the second IDT electrode including a third comb-shaped electrode and a fourth comb-shaped electrode interdigitated with each other; wherein
the first, second and third comb-shaped electrodes are each connected to the input terminal, the output terminal, or a ground terminal, and the fourth comb-shaped electrode is a floating electrode that is not connected to any of the input terminal, the output terminal, and the ground terminal;
the first, second, third and fourth comb-shaped electrodes each include a busbar, a plurality of electrode fingers connected to the busbar, and a plurality of dummy electrodes connected to the busbar, and the plurality of dummy electrodes face the plurality of electrode fingers of each interdigitated comb-shaped electrode, in an intersecting width direction; and
a distance between an electrode finger or a dummy electrode of the first IDT electrode and an adjacent electrode finger or an adjacent dummy electrode of the fourth comb-shaped electrode is longer than a distance between the electrode finger or the dummy electrode of the first IDT electrode and an adjacent electrode finger or an adjacent dummy electrode of the third comb-shaped electrode.

2. The elastic wave filter according to claim 1, wherein an outermost electrode finger located on the first IDT electrode side, among the plurality of electrode fingers of the third and fourth comb-shaped electrodes, is an electrode finger of the third comb-shaped electrode, and the fourth comb-shaped electrode is not provided with a dummy electrode facing the outermost electrode finger located on the first IDT electrode side in the intersecting width direction.

3. The elastic wave filter according to claim 2, wherein an end portion of the busbar on the first IDT electrode side, of the fourth comb-shaped electrode, is located on the other side of the propagation direction of elastic waves with respect to the outermost electrode finger located on the first IDT electrode side.

4. The elastic wave filter according to claim 1, wherein at least one of the busbar of the fourth comb-shaped electrode and the busbar of one of the first and second comb-shaped electrodes, which is disposed on the same side as the fourth comb-shaped electrode in the intersecting width direction, includes a protruding portion, and the protruding portion faces a portion or a protruding portion of the other busbar.

5. The elastic wave filter according to claim 4, wherein a distance between the portions facing each other is shorter than a distance between the electrode finger or the dummy electrode of the first IDT electrode and the adjacent electrode finger or the adjacent dummy electrode of the fourth comb-shaped electrode.

6. The elastic wave filter according to claim 1, wherein the piezoelectric substrate is composed of LiNbO₃, LiTaO₃ or quartz.

7. The elastic wave filter according to claim 1, wherein the elastic wave filter is a surface acoustic wave filter or a boundary acoustic wave filter.

8. The elastic wave filter according to claim 7, wherein the elastic wave filter is a three-medium boundary acoustic wave filter including two dielectric layers located on the piezoelectric substrate.

9. The elastic wave filter according to claim 7, wherein the elastic wave filter is a two-medium boundary acoustic wave filter including one dielectric layer located on the piezoelectric substrate.

10. The elastic wave filter according to claim 4, wherein the protruding portion has one of a rectangular shape, a substantially rectangular shape, a triangular shape, or a substantially triangular shape.

11. An elastic wave filter comprising:
an input terminal;
an output terminal; and
an elastic wave filter unit connected between the input terminal and the output terminal, the elastic wave filter unit including:
a piezoelectric substrate;
a first IDT electrode located on the piezoelectric substrate, the first IDT electrode including a first comb-shaped electrode and a second comb-shaped electrode interdigitated with each other, the first and second comb-shaped electrodes each connected to the input terminal, the output terminals, or a ground terminal; and
a second IDT electrode located on the piezoelectric substrate on one side of the first IDT electrode in a propagation direction of elastic waves, the second IDT electrode including third and fourth comb-shaped electrodes interdigitated with each other; wherein
the first, second and third comb-shaped electrodes are each connected to the input terminal, the output terminals, or a ground terminal, and the fourth comb-shaped electrode is a floating electrode that is not connected to any of the input terminal, the output terminals, and the ground terminal;
the first, second, third and fourth comb-shaped electrodes each include a busbar, a plurality of electrode fingers connected to the busbar, and a plurality of dummy electrodes connected to the busbar, and the plurality of dummy electrodes face the plurality of electrode fingers of each interdigitated comb-shaped electrode in an intersecting width direction; and
at least one of the busbar of the fourth comb-shaped electrode and the busbar of one of the first and second comb-shaped electrodes, which is disposed on the same side as the fourth comb-shaped electrode in the intersecting width direction, includes a protruding portion, and the protruding portion faces a portion or a protruding portion of the other busbar in the intersecting width direction.

12. The elastic wave filter according to claim 11, wherein an outermost electrode finger located on the first IDT electrode side, among the plurality of electrode fingers of the third and fourth comb-shaped electrodes, is an electrode finger of the third comb-shaped electrode, and the fourth comb-shaped electrode is not provided with a dummy electrode facing the outermost electrode finger located on the first IDT electrode side in the intersecting width direction.

13. The elastic wave filter according to claim 12, wherein an end portion of the busbar on the first IDT electrode side, of the fourth comb-shaped electrode, is located on the other side of the propagation direction of elastic waves with respect to the outermost electrode finger located on the first IDT electrode side.

14. The elastic wave filter according to claim 11, wherein at least one of the busbar of the fourth comb-shaped electrode and the busbar of one of the first and second comb-shaped electrodes, which is disposed on the same side as the fourth comb-shaped electrode in the intersecting width direction, includes a protruding portion, and the protruding portion faces a portion or a protruding portion of the other busbar.

15. The elastic wave filter according to claim 14, wherein a distance between the portions facing each other is shorter than a distance between the electrode finger or the dummy electrode of the first IDT electrode and the adjacent electrode finger or the adjacent dummy electrode of the fourth comb-shaped electrode.

16. The elastic wave filter according to claim 11, wherein the piezoelectric substrate is composed of LiNbO₃, LiTaO₃ or quartz.

17. The elastic wave filter according to claim 11, wherein the elastic wave filter is a surface acoustic wave filter or a boundary acoustic wave filter.

18. The elastic wave filter according to claim 17, wherein the elastic wave filter is a three-medium boundary acoustic wave filter including two dielectric layers located on the piezoelectric substrate.

19. The elastic wave filter according to claim 17, wherein the elastic wave filter is a two-medium boundary acoustic wave filter including one dielectric layer located on the piezoelectric substrate.

20. The elastic wave filter according to claim 14, wherein the protruding portion has one of a rectangular shape, a substantially rectangular shape, a triangular shape, or a substantially triangular shape.
